(19) United States
(12) Patent Application Publication
(10) Pub. No.: US 2026/0334335 A1
(43) Pub. Date: Oct. 22, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: Roger St. Amand, Tempe, AZ (US); Mike Kelly, Mesa, AZ (US); Doug Scott, Scottsdale, AZ (US)

(73) Assignee: Amkor Technology Singapore Holding Pte. Ltd., (omitted)

(21) Appl. No.: 19/647,624

(22) Filed: Apr. 14, 2026

Related U.S. Application Data
(60) Provisional application No. 63/789,631, filed on Apr. 16, 2025.

(51) Int. Cl. H10W 90/00; H10W 70/05; H10W 90/10

(52) U.S. Cl. CPC H10W 90/401; H10W 70/096; H10W 90/10

(57) ABSTRACT

In one example, a method of making an electronic device can include providing a first subpanel on a panel carrier. The first subpanel includes first substrates. A second subpanel can be provided on the panel carrier with a gap defined between the first subpanel and the second subpanel. The second subpanel comprises second substrates. A first redistribution structure is provided over a first side of the first substrates and the second substrates. The first redistribution structure is coupled to first contacts of the first substrates and second contacts of the second substrates. A second redistribution structure is provided over a second side of the first substrates and the second substrates opposite the first side. Other examples and related methods are also disclosed herein.

### CROSS REFERENCE TO RELATED APPLICATIONS

This application claims priority to U.S. Provisional Patent Application No. 63/789,631, filed on Apr. 16, 2025, and entitled “ELECTRONIC DEVICES AND METHODS OF MANUFACTURING ELECTRONIC DEVICES,” which is incorporated herein in its entirety.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2X show an example method of making a signal distribution structure for an electronic device using cross-sectional views.

FIGS. 3A to 3D show an example method of making an electronic device using cross-sectional views.

FIGS. 4A to 4N show an example method of making a signal distribution structure for an electronic device using cross-sectional views.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein as labels to describe various elements, and these elements should not be limited by these terms. These terms are only used to distinguish one element from another. Thus, for example, a first element discussed in this disclosure could be termed as a second element elsewhere without departing from the teachings of the present disclosure. Similarly, terms disclosed as singular can be plural in some embodiments, and elements disclosed as plural can be singular in some embodiments.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other, describe two elements indirectly coupled by one or more other elements, or two elements overlapping vertically as depicted. Unless specified otherwise, the term “coupled” can refer to a mechanical coupling or an electrical coupling.

### DESCRIPTION

Various examples include redistribution layers (RDLs) formed on both an upper and lower side of a substrate at the panel level. In one example, an electronic device comprises a panel carrier and subpanels disposed over the panel carrier and defining gaps between the subpanels. The subpanels comprise substrates. A first redistribution structure is formed over a first side of the subpanels. The first redistribution structure extends across the gaps between the subpanels. A second redistribution structure formed over a second side of the subpanels and opposite the first side of the subpanels. The second redistribution structure extends across the gaps between the subpanels.

In various examples, an insulating material is disposed in the gaps between the subpanels. The insulating material is disposed between the first redistribution structure and the second redistribution structure. A film can be coupled to a first subpanel and extending between adjacent substrates in the first subpanel.

An example method comprises the steps of singulating first substrates from a first wafer, placing the first substrates over a first carrier, and encapsulating the first substrates to produce a first encapsulated subpanel. The example method further includes singulating second substrates from a second wafer, placing the second substrates over a second carrier, and encapsulating the second substrates to produce a second encapsulated subpanel comprising the second substrates. The first encapsulated subpanel and the second encapsulated subpanel are placed over a third carrier. A first redistribution structure is formed over a first side of the first encapsulated subpanel and the second encapsulated subpanel. The first redistribution structure extends across a gap defined between the first encapsulated subpanel and the second encapsulated subpanel. A second redistribution structure is formed over a second side of the first encapsulated subpanel and the second encapsulated subpanel. The second redistribution structure extends across the gap defined between the first encapsulated subpanel and the second encapsulated subpanel. The second side is opposite the first side.

In various examples, encapsulating the first substrates comprises providing a mold material between the first substrates. Encapsulating the first substrates can include providing a dry film between the first substrates. Encapsulating the first substrates can comprise providing a spray-coated dielectric between the first substrates. Singulating the first substrates from the first wafer includes singulating the first substrates into substrate blocks that include a plurality of the first substrates coupled together.

In some examples, a signal distribution structure is singulated from the first encapsulated subpanel. The signal distribution structure can include one of the first substrates coupled between a portion of the first redistribution structure and a portion of the second redistribution structure. The signal distribution structure is placed on a boat, and an electronic component is coupled to the first redistribution structure. A lid can be coupled to the first redistribution structure around an outer perimeter of the electronic component. Component interconnects are coupled to the second redistribution structure. Contacts can be coupled to an exposed side of the first substrates, the first substrates and the contacts can be covered with a mold material, and a portion of the mold material is removed to expose a side of the contacts coplanar with a side of the mold material. The first encapsulated subpanel and the second encapsulated subpanel can both comprise dimensions greater than 200 millimeters (mm) by 200 mm. The third carrier comprises a panel carrier having dimensions greater than 500 millimeters (mm) by 500 mm.

In another example, a method of making an electronic device can include providing a first subpanel on a panel carrier. The first subpanel includes first substrates. A second subpanel can be provided on the panel carrier with a gap defined between the first subpanel and the second subpanel. The second subpanel comprises second substrates. A first redistribution structure is provided over a first side of the first substrates and the second substrates. The first redistribution structure is coupled to first contacts of the first substrates and second contacts of the second substrates. A second redistribution structure is provided over a second side of the first substrates and the second substrates opposite the first side.

In various examples, the second subpanel comprises a block including at least two of the second substrates formed integrally. In some examples, an encapsulant is provided around the first substrates to form the first subpanel, and the encapsulant is planarized with contacts extending from a first side of the first substrates. Singulation can be performed through the first redistribution structure and the second redistribution structure to provide a strip of signal distribution structures. Each signal distribution structure of the strip of signal distribution structures can include a first substrate coupled between a portion of the first redistribution structure and a portion of the second redistribution structure. The panel carrier can include a surface area greater than 250,000 square millimeters.

Other examples are included in the present disclosure. Such examples may be found in the figures, in the claims, or in the description of the present disclosure.

Electronic devices and methods of manufacture can comprise signal distribution structures having redistribution layers (RDLs) formed on both upper and lower sides of substrates at the panel level. By singulating and repositioning components (e.g., substrates) from multiple wafers on a carrier, RDL formation over multiple components can be performed on a larger scale (e.g., 500 millimeter (mm)×500 mm, 600 mm×600 mm, 650 mm×650 mm, or other suitable size) versus a scale of 300 mm×300 mm. Larger batches enable processing of more substrates per batch.

As used herein, the term subpanel can mean a panel having dimensions of approximately 200 mm×200 mm, approximately 250 mm×250 mm, or approximately 300 mm ×300 mm. As used herein, the term panel can mean a panel having dimensions of approximately 500 mm×500 mm, approximately 550 mm×550 mm, approximately 600 mm×600 mm, or approximately 650 mm×650 mm, or can mean a panel comprising multiple subpanels. While symmetric dimensions are given as examples, panels can be irregularly or asymmetrically shaped. As used herein with numeric values or dimensions, the term approximately can mean +/−5%, +/−10%, +/−15%, +/−20%, or +/−25%.

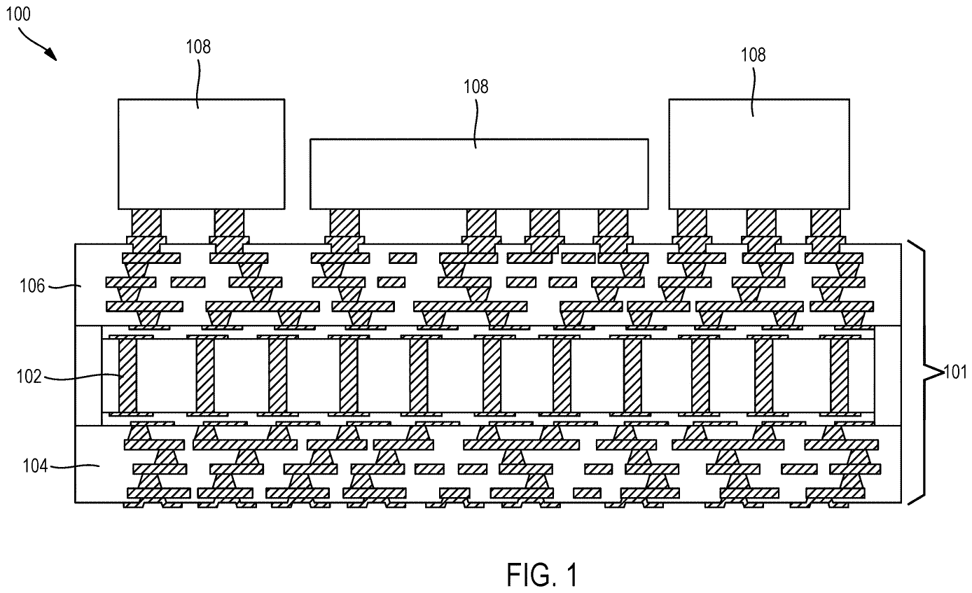

Referring now to FIG. 1, example electronic device 100 is shown, in accordance with various examples. Example electronic device 100 comprises signal distribution structure 101 and electronic components 108. Signal distribution structure 101 comprises substrate 102, redistribution structure 104, and redistribution structure 106. Substrate 102 can be coupled between redistribution structure 104 and redistribution structure 106. Electronic components 108 can be coupled to signal distribution structure 101. Signal distribution structure 101 can be formed at the panel level. For example, redistribution structure 104 and redistribution structure 106 can be formed over substrate 102 in panel form.

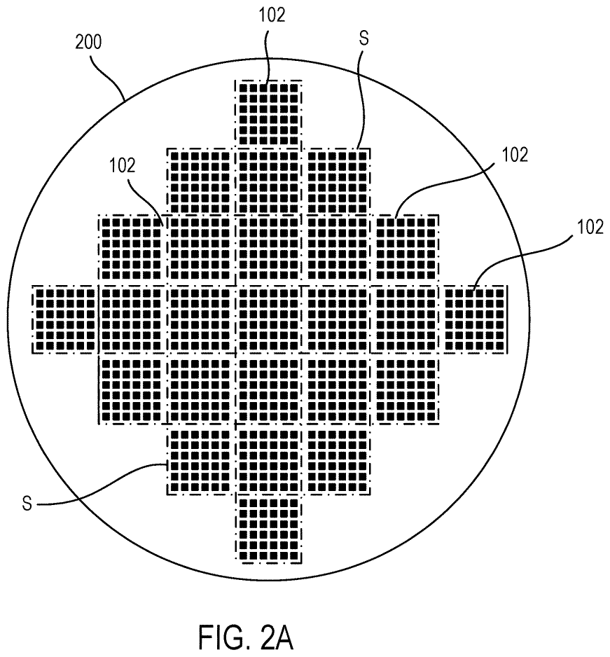

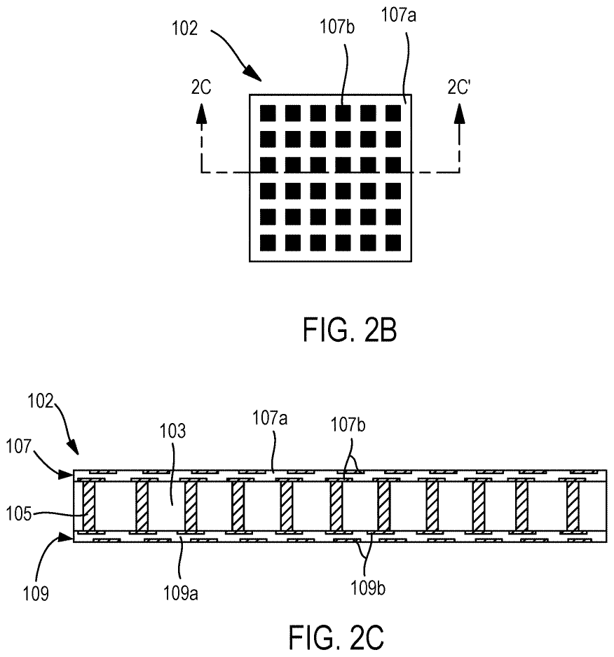

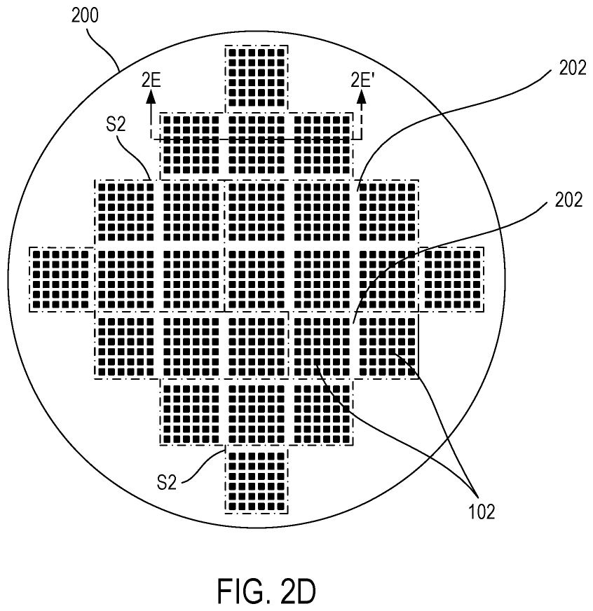

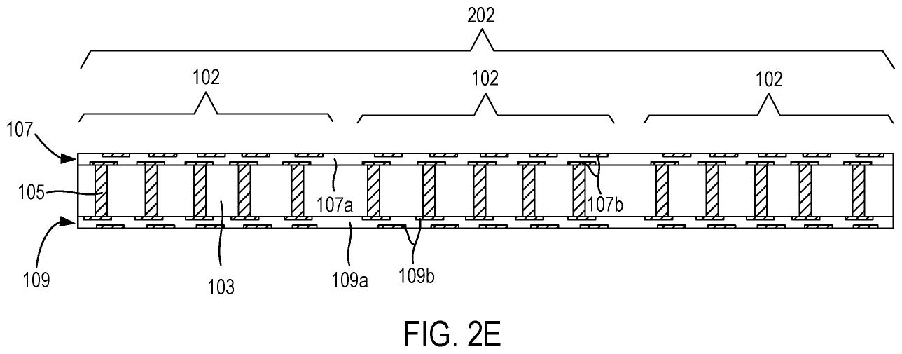

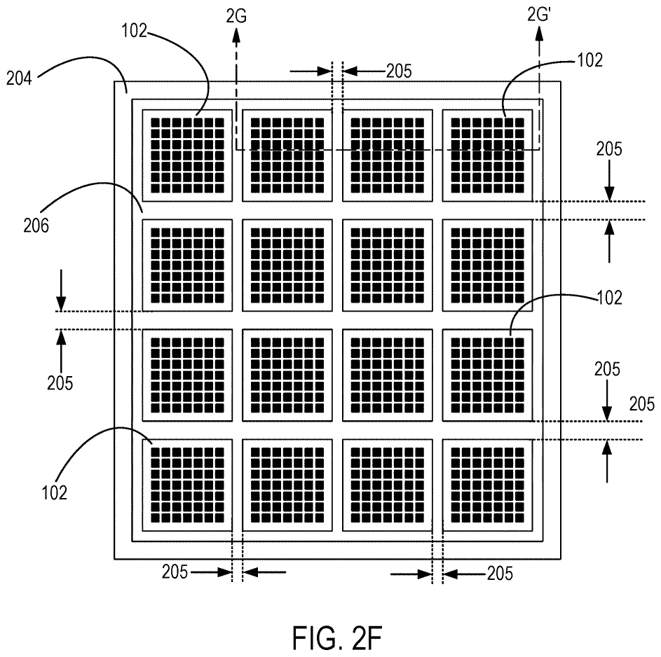

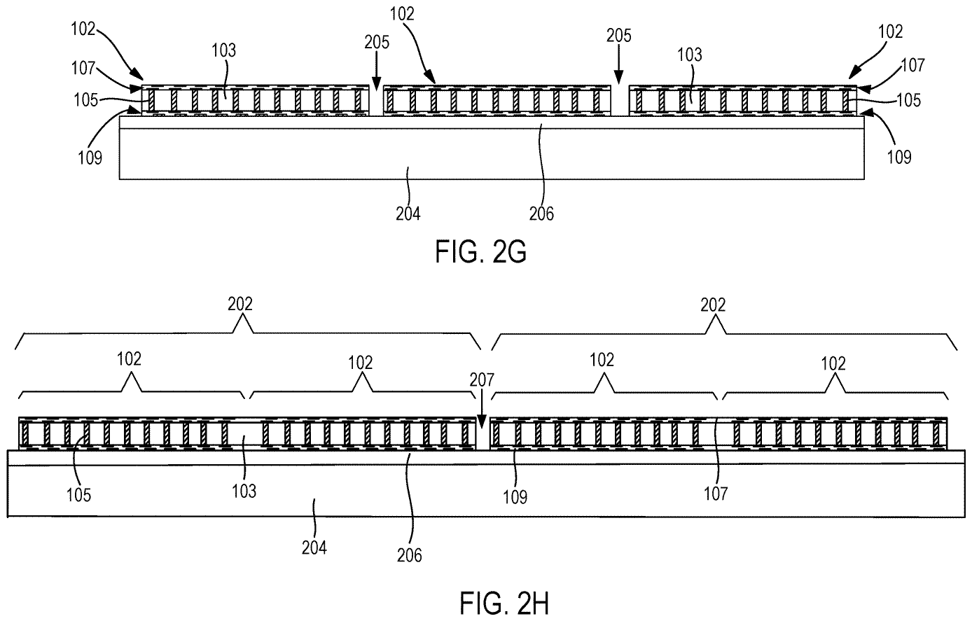

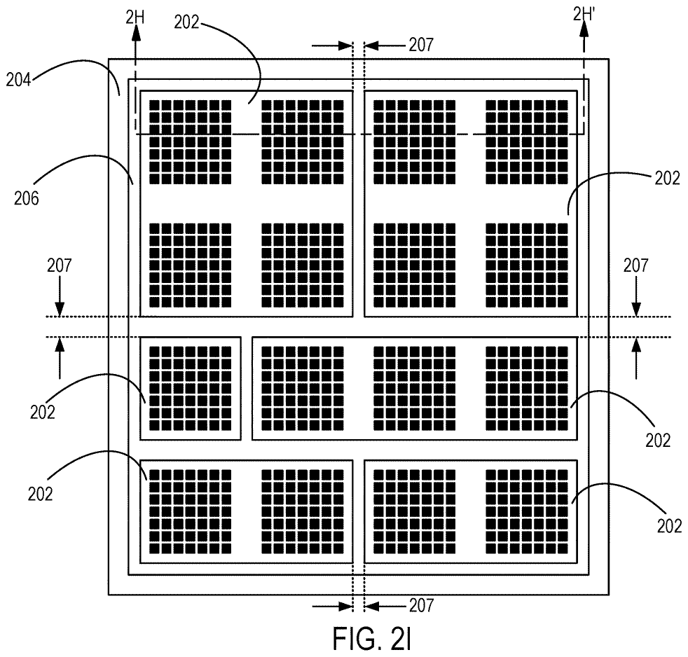

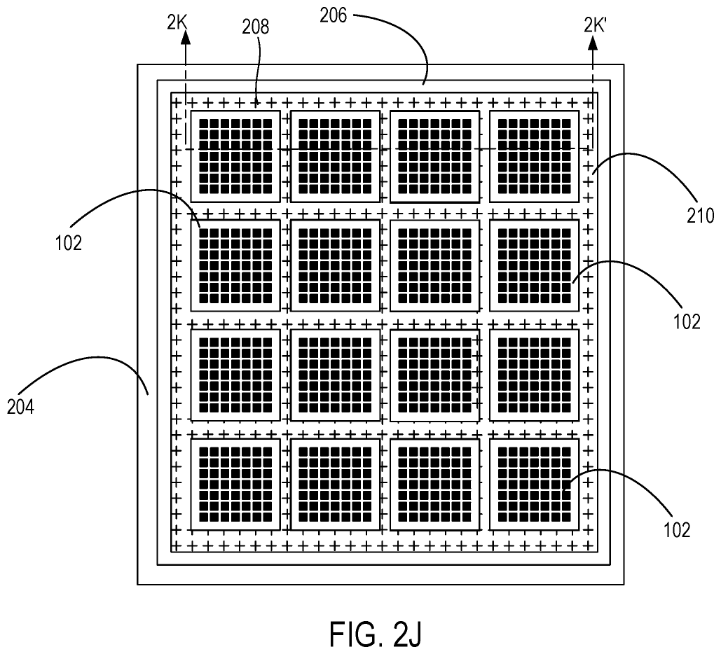

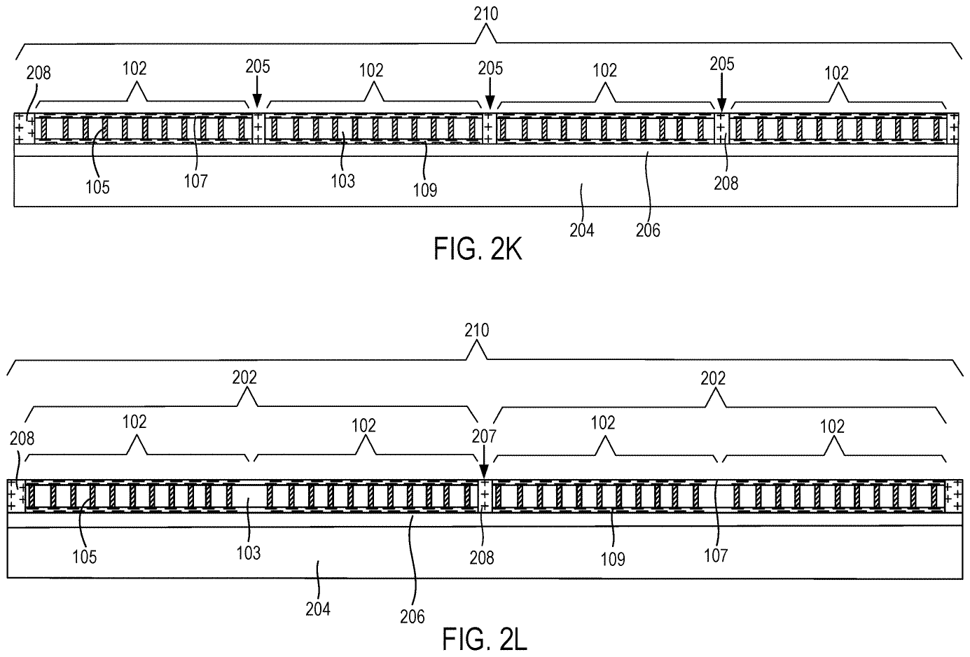

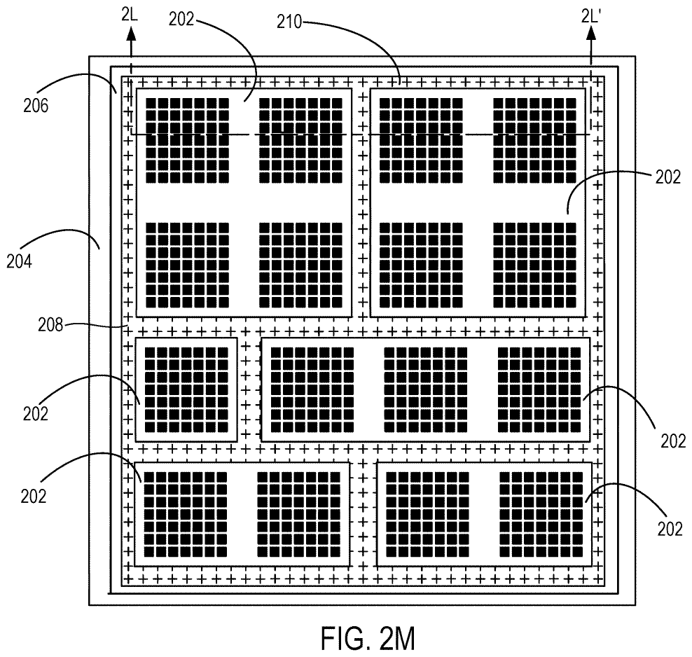

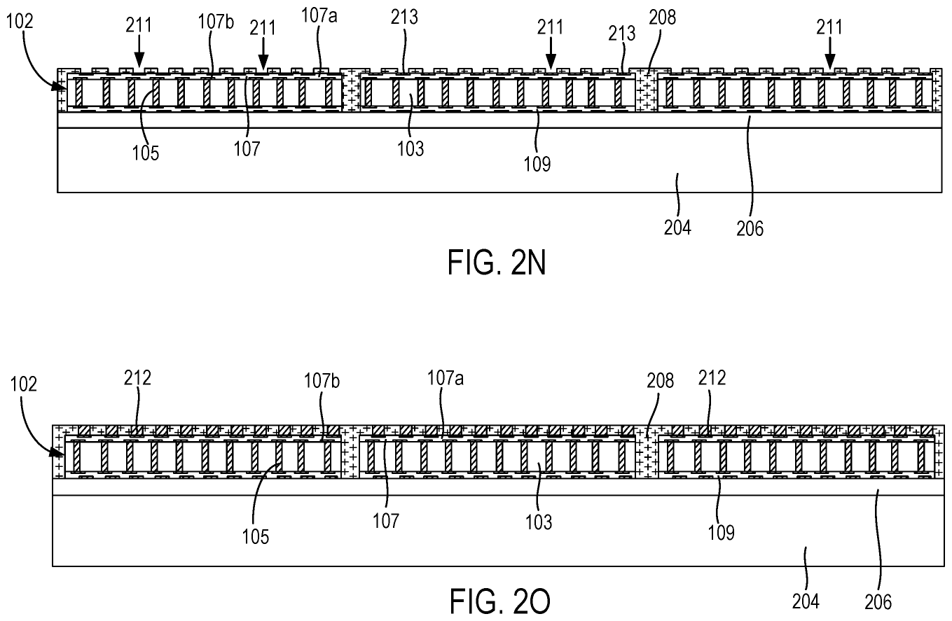

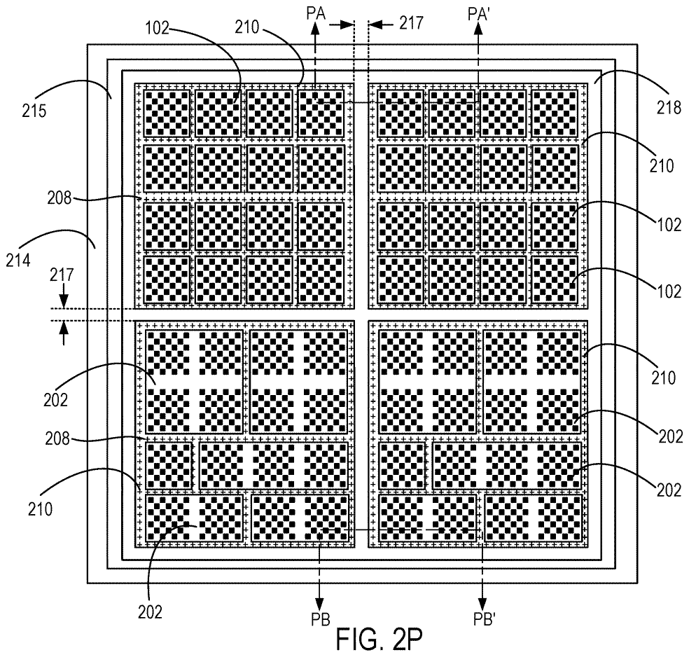

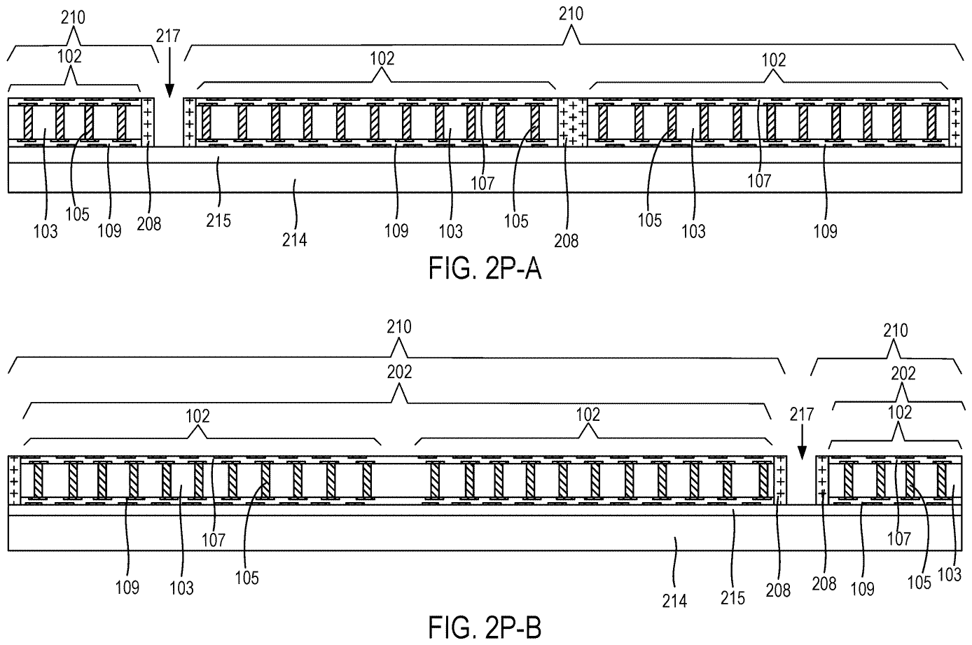

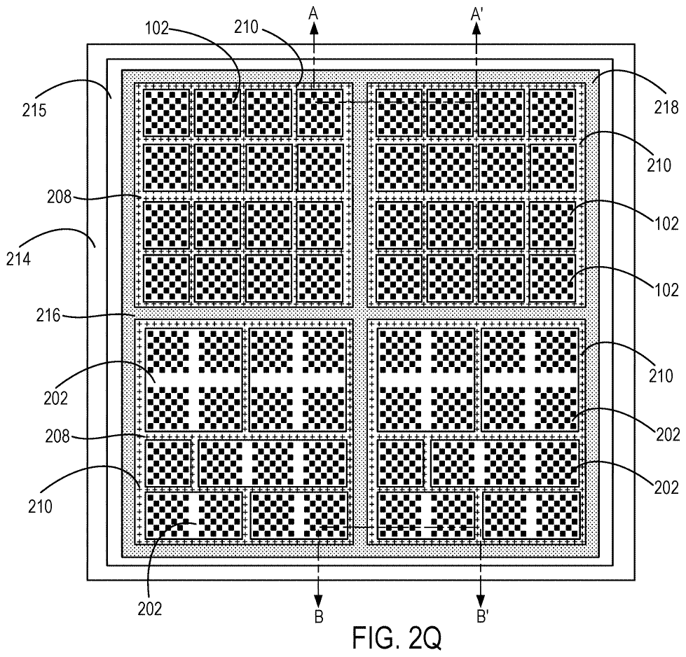

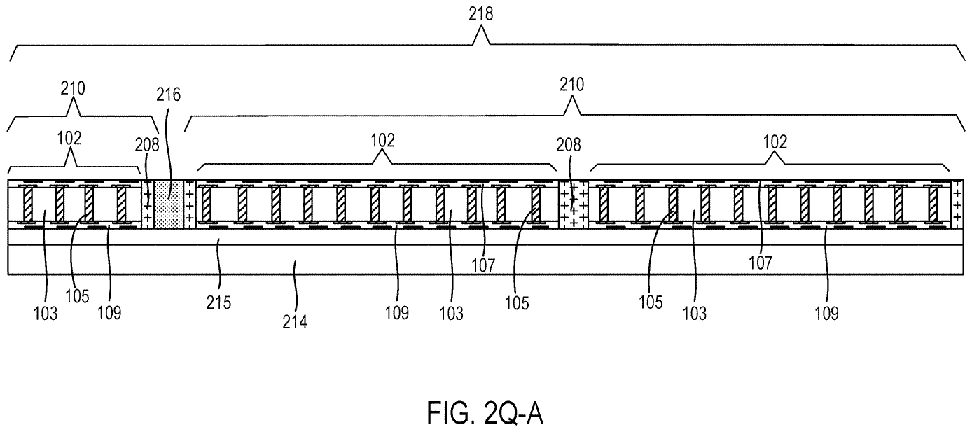

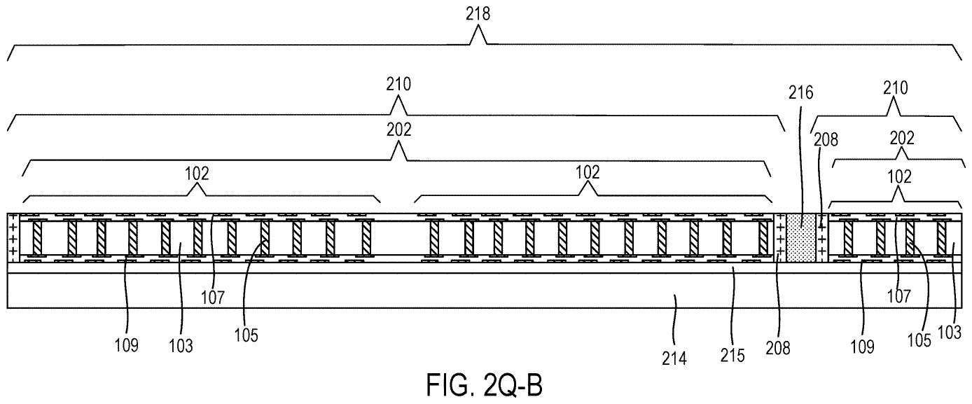

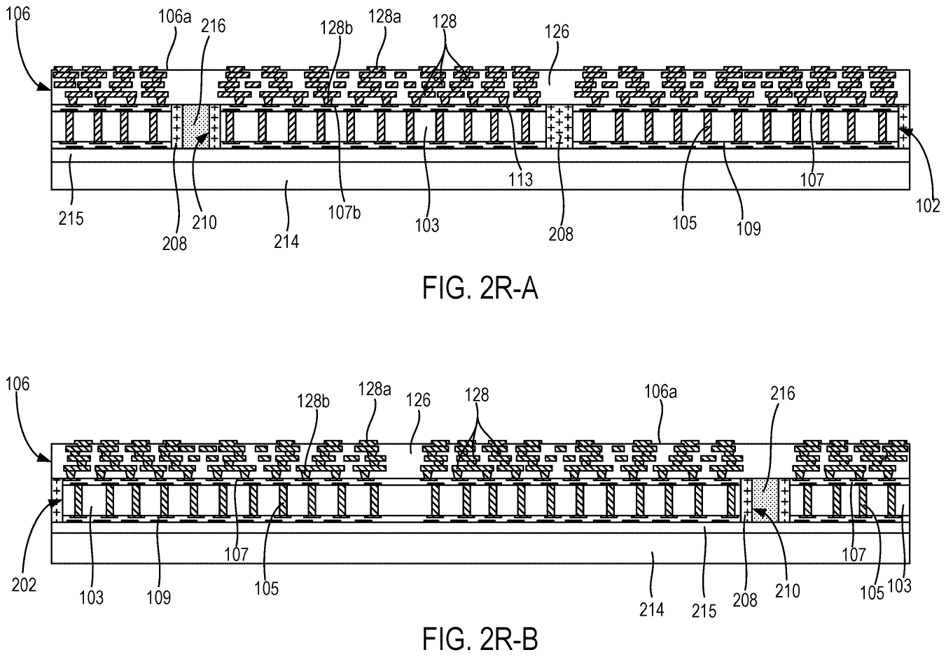

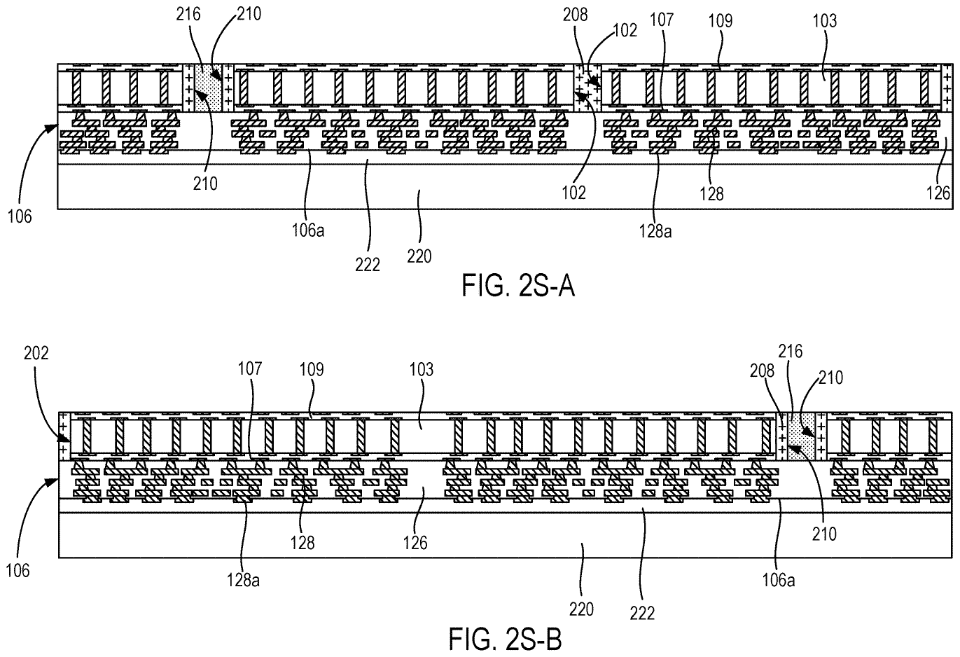

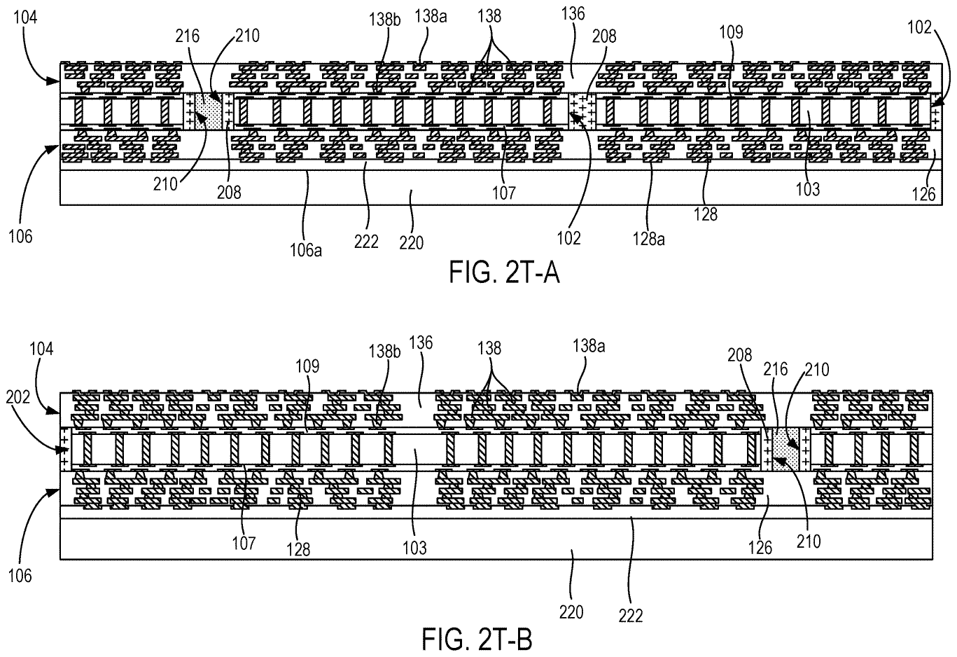

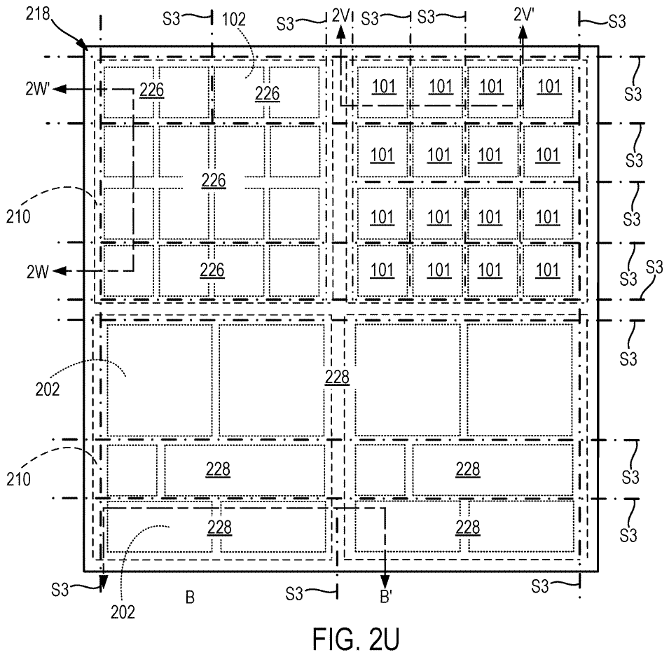

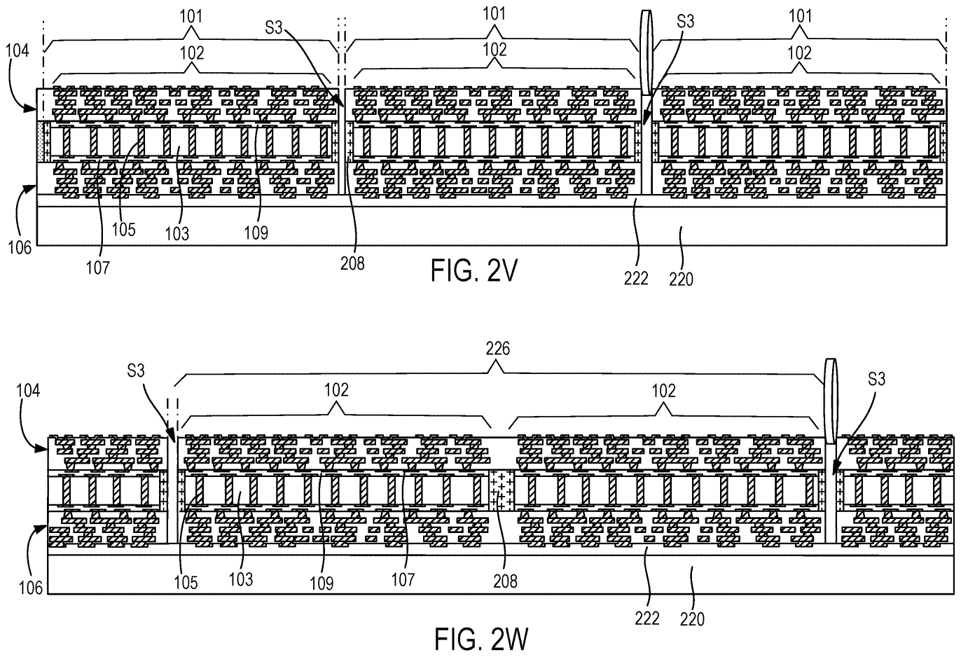

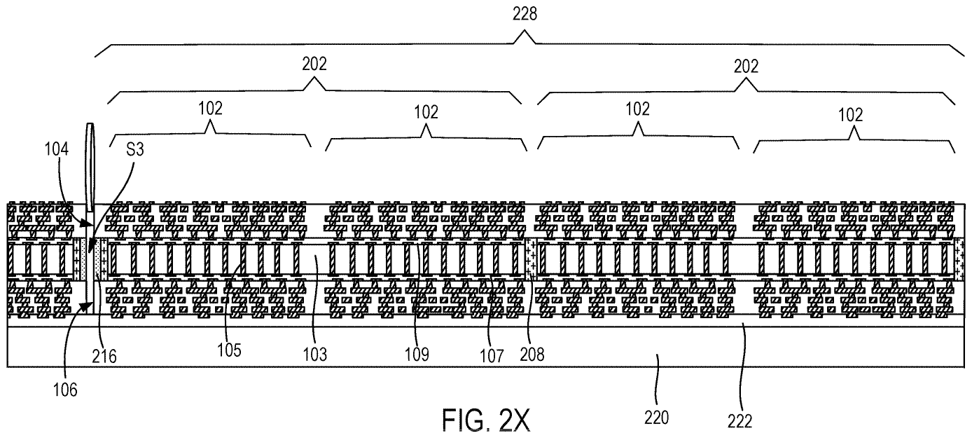

Referring now to FIGS. 2A-2X, a method of manufacturing signal distribution structure 101 is shown, in accordance with various examples. FIGS. 2A, 2B, and 2C show signal distribution structure 101 at an early stage of manufacture. In the example of FIG. 2A, a wafer 200 including substrates 102 is provided. Substrates 102 can be singulated from wafer 200. For example, singulation can be performed by cutting through saw streets (indicated by dashed lines S in FIG. 2A) disposed around the perimeter of individual substrates 102, thereby separating individual substrate 102 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting).

In the example of FIGS. 2B and 2C, a top view and a cross-section view, taken along line 2C-2C′ in FIG. 2B, of a singulated substrate 102 are shown, respectively. In accordance with various examples, substrate 102 can comprise a core 103 and conductive structure 105. Conductive structure 105 can extend through core 103 and can provide an electrical path between opposing sides of core 103. Conductive structure 105 can comprise or be referred to as a plurality of conductive vias, through vias, through mold vias (TMV), through silicon vias (TSV), through glass vias (TGV), vertical interconnects, or interconnect structures. Conductive structure 105 can comprise copper (Cu), aluminum (Al), titanium (Ti), titanium tungsten (TiW), tin (Sn), nickel (Ni), gold (Au), silver (Ag), or other suitable electrically conductive material. In some examples, conductive structure 105 can also include contact pads or under-bump metallization (UBM) formed on opposing sides of the conductive vias. Core 103 can comprise glass, semiconductor material (e.g., silicon (Si), germanium (Ge), gallium arsenide (GaAs), or gallium nitride (GaN)), or mold.

In some examples, substrate 102 can comprise a substrate redistribution structure 107 formed over an inner side of core 103. Substrate redistribution structure 107 can comprise dielectric structure 107a and conductive structure 107b. In accordance with various examples, one or more layers of dielectric structure 107a can be interleaved with one or more elements or layers of conductive structure 107b (e.g., traces, vias, pads, etc.) to form substrate redistribution structure 107. In some examples, the conductive material(s) of conductive structure 107b can comprise one or more layers of Cu, Al, Ti, TiW, Sn, Ni, Au, Ag, or other suitable electrically conductive material. Conductive structure 107b is coupled to conductive structure 105. For example, conductive structure 107b can contact an inner side of conductive vias 105.

In some examples, the dielectric material(s) of dielectric structure 107a can comprise one or more inorganic dielectric layers. Some examples of inorganic dielectric layers can comprise silicon nitride (Si3N4), silicon oxide (SiO2), and/or silicon oxynitride SiON. The inorganic dielectric layers can be formed by growing the inorganic dielectric layers using an oxidation or nitridization process instead of using photo-defined organic dielectric materials. Such inorganic dielectric layers can be filler-free, without strands, weaves, or other dissimilar inorganic particles. In some examples, the dielectric material(s) of dielectric structure 107a can comprise one or more organic dielectric layers, such as, for example, polyimide (Pl), benzocyclobutene (BCB), or polybenzoxazole (PBO).

In some examples, substrate 102 can comprise substrate redistribution structure 109 formed over an outer side of core 103, opposite substrate redistribution structure 107. Substrate redistribution structure 109 can comprise dielectric structure 109a and conductive structure 109b. In accordance with various examples, one or more layers of dielectric structure 109a can be interleaved with one or more layers or elements of conductive structure 109b (e.g., traces, vias, pads, etc.) to form substrate redistribution structure 109. In some examples, the conductive material(s) of conductive structure 109b can comprise one or more layers of Cu, Al, Ti, TiW, Sn, Ni, Au, Ag, or other suitable electrically conductive material. Conductive structure 109b is coupled to and/or can contact an outer side of conductive structure 105. In some examples, the dielectric material(s) of dielectric structure 109a can comprise one or more inorganic dielectric layers (e.g., Si3N4, SiO2, and/or SiON). In other examples, the dielectric material(s) of dielectric structure 109a can comprise one or more organic dielectric layers, such as, for example, Pl, BCB, or PBO.

Referring now to FIGS. 2D and 2E, in some examples, wafer 200 can be singulated along saw streets S2 to provide blocks 202 of substrates 102. FIGS. 2D and 2E show an example of singulation of wafer 200 into blocks 202, with FIG. 2E showing a cross-section view taken along line 2E-2E′ in FIG. 2D. In accordance with various examples, blocks 202 can comprise one or more substrates 102 formed integrally and remaining coupled together after singulation. In the example of FIG. 2D, blocks 202 are shown in a 1×1, 2×2, 3×2, 3×1, and 2×1 substrate configuration, but blocks 202 can comprise any desirable number and arrangement of substrates 102. As described in further detail below, individual substrates 102 or blocks 202 singulated from wafer 200 can be integrated into a panel that is larger than wafer 200 for processing of multiple substrates 102 from multiple wafers 200.

FIGS. 2F and 2G show, respectively, a plan view and a cross-section view of signal distribution structure 101 at a later stage of manufacture. The cross-section view of FIG. 2G is taken along line 2G-2G′ in FIG. 2F. In the example of FIGS. 2F and 2G, substrates 102 can be provided over a carrier 204. In some examples, carrier 204 can comprise or be referred to as a subpanel carrier, a temporary carrier, a support structure, or a plate. Carrier 204 can comprise semiconductor material, glass, metal, ceramic, etc. In some examples, a temporary bonding layer 206 can be provided on the upper side of carrier 204. Temporary bonding layer 206 can comprise or be referred to as a temporary bonding film, a temporary bonding tape, or a temporary adhesive coating. For example, temporary bonding layer 206 can comprise a heat release tape (film or coating), an optical release tape (film or coating), a chemical release tape (film or coating), or a laser release tape (film or coating), wherein the adhesive strength of temporary bonding layer 206 is weakened or removed by heat, light, chemical reaction, or laser energy, respectively.

Individual substrates 102 can be coupled to carrier 204 by temporary bonding layer 206. Temporary bonding layer 206 can facilitate separation of substrates 102 from carrier 204 at a later stage of manufacture. In some examples, physical force can be used solely or in addition to heat, light, chemical reaction, and/or laser energy to separate substrates 102 from carrier 204. In some examples, carrier 204 can comprise a subpanel carrier having dimensions of approximately 300 mm×300 mm. Substrates 102 can be arranged on carrier 204 with gaps or channels 205 defined between adjacent substrates 102.

Referring now to FIGS. 2H and 2I, in some examples, substrate blocks 202 can be provided over carrier 204. FIGS. 2H and 2I show, respectively, a cross-section view and a plan view of blocks 202 over carrier 204. The cross-section view of FIG. 2H is taken along line 2H-2H′ in FIG. 2I. In accordance with various examples, substrate blocks 202 can be arranged over carrier 204 to maximize the numbers of substrates 102 processed on carrier 204. Substrate blocks 202 can be coupled to carrier 204 by temporary bonding 206. Substrate blocks 202 can be arranged on carrier 204 with gaps or channels 207 defined between adjacent substrate blocks 202. In some examples, substrate blocks 202 can be coupled to carrier 204 by temporary bonding layer 206. Temporary bonding layer 206 can facilitate separation of substrate blocks 202 from carrier 204 at a later stage of manufacture.

FIGS. 2J and 2K. show a plan view and a cross-section view of signal distribution structure 101 at a later stage of manufacture. FIG. 2K is a cross-section view taken along line 2K-2K′ in FIG. 2J. In the example of FIGS. 2J and 2K, encapsulant 208 can be provided between substrates 102 to form encapsulated subpanel 210. For example, encapsulant 208 can be provided in channels 205 between adjacent substrates 102. Encapsulant 208 can be disposed around the lateral sides of substrates 102. The upper or exposed side of encapsulant 208 (i.e., the side opposite carrier 204) can be substantially coplanar with upper or exposed side of substrates 102. As used herein with reference to qualitative characteristics such as flat or coplanar, the term substantially can mean within manufacturing tolerances.

In various examples, encapsulant 208 can comprise or be referred to as a package body, encapsulating structure, a mold, mold material, an epoxy molding compound, a resin, a filler-reinforced polymer, a B-stage compressed film, or gel. Encapsulant 208 can be provided by transfer molding, compression molding, liquid encapsulant molding, vacuum lamination, paste printing, film assisted molding, or other suitable processes.

Referring now to FIGS. 2L and 2M, in some examples, encapsulant 208 can be provided between substrate blocks 202 to form encapsulated subpanel 210. For example, encapsulant 208 can be provided in channels 207 between adjacent substrate blocks 202. Encapsulant 208 can be disposed around the lateral sides of substrate blocks 102. The upper or exposed side of encapsulant 208 (i.e., the side opposite carrier 204) can be substantially coplanar with upper or exposed side of substrate blocks 202.

In accordance with various examples, encapsulated subpanels 210 can comprise substrates 102 or substrate blocks 202 coupled together by encapsulant 208. In some examples, film assisted molding can be performed to inhibit encapsulant 208 from flowing over the upper or exposed side of substrates 102 or substrate blocks 202.

In some examples, encapsulant 208 can be provided over an upper side of substrates 102, as shown in the examples of FIGS. 2N and 2O. While FIGS. 2N and 2O show encapsulant 208 over individual substrates 102, it is comprehended and understood that encapsulant 208 can be provided over the upper sides of substrate blocks 202 in some examples.

In various examples, encapsulant 208 can extend above the upper side of substrates 102 or blocks 202. With reference to FIG. 2N, in some examples, encapsulant 208 can be selectively removed to form openings 211. Openings 211 can be formed over and can expose outer pads 213 of substrate 102. Openings 211 can be formed using a laser ablation or any other suitable mold removal technique. Pads 213 can comprise under bump metallization (UBM), traces, I/O pads, or other structures of conductive structure 107b. For example, outer pads 213 can be part of conductive structure 107b and can be exposed from dielectric structure 107a at a side of dielectric structure 107a that is opposite core 103. Pads 213 can be recessed relative to encapsulant 208.

Referring to FIG. 2O, in some examples, a back grinding and/or etching operation(s) can be used to remove a portion of encapsulant 208 from over the upper side of substrates 102 or blocks 202. In some examples, the removal of encapsulant 208 can reveal contacts 212 of substrate 102. For example, substrates 102 can be provided with contacts 212 on outer pads 213. Encapsulant 208 can be disposed over and between adjacent contacts 212. After removal of encapsulant 208, contacts 212 are exposed from encapsulant 208, and the upper sides of contacts 212 can be coplanar with the upper side of encapsulant 208. In some examples, a portion of contacts 212 can also be removed during the removal of encapsulant 208 (e.g., during backgrinding). Removal of encapsulant 208 (and contacts 212) can provide a substantially flat surface and can compensate for any nonplanarity of substrate 102. Providing a flat surface can better support a redistribution layer (RDL) build up process, as described in further detail below. Contacts 212 can comprise studs, pillars, posts, bumps, or other conductive structures electrically coupled to outer pads 213 of substrates 102 or blocks 202. Encapsulant 208 and contacts 212 can be substantially coplanar over different substrates 102 and blocks 202. The flat upper side can span contacts 212 and encapsulant 208, and the flat upper side can provide a flat surface which supports an RDL process across multiple substrates 102 and blocks 202, as described in further detail below.

FIGS. 2P, 2P-A, and 2P-B show a plan view and cross-section views, respectively, of signal distribution structure 101 at a later stage of manufacture. In the example of FIG. 2P, subpanels 210 comprising individual substrates 102 (FIGS. 2J, 2K) and subpanels 210 comprising blocks 202 (FIGS. 2L, 2M) are located over carrier 214 to form panel 218. FIG. 2P-A shows a cross section of subpanels 210 comprising individually singulated substrates 102 taken along line PA-PA′ in FIG. 2P. FIG. 2P-B shows a cross section of subpanels 210 comprising substrate blocks 202 taken along line PB-PB′ in FIG. 2P. While FIGS. 2P, 2P-A, and 2P-B and subsequent figures show encapsulated subpanels 210 having encapsulant 208 coplanar with the upper side of redistribution structure 107 (as shown in FIGS. 2K and 2M), it is contemplated and understood that, in some examples, encapsulated subpanels 210 having encapsulant 208 extending above the upper side of redistribution structure 107 (as shown in FIGS. 2N and 2O) can be used to manufacture signal distribution structure 101.

In the example of FIGS. 2P, 2P-A, and 2P-B, encapsulated subpanel 210 can be removed from subpanel carrier 204 (FIGS. 2J and 2M) and provided over panel carrier 214. In accordance with various examples, channels or gaps 217 can be defined between adjacent subpanels 210. In some examples, a temporary bonding layer 215, similar to temporary bonding layer 206, can be disposed on the upper side of panel carrier 214, between subpanels 210 and panel carrier 214.

In accordance with various examples, multiple encapsulated subpanels 210 can be provided over carrier 214. Carrier 214 is larger in area than carrier 204 and can thus support multiple encapsulated subpanels 210. For example, four 300 mm by 300 mm or smaller subpanels 210 can be repopulated onto carrier 214. Continuing the example, carrier 214 can have dimensions of approximately 500 mm×500 mm, approximately 600 mm×600 mm, approximately 650 mm ×650 mm, or other suitable sizes. In some examples, the individual, singulated substrates 102 or substrate blocks 202 can be repopulated directly onto the larger panel carrier 214, and encapsulant 208 can be provided over panel carrier 214. The surface area of a carrier can be the product of its dimensions. For example, a 500 mm×500 mm can have a surface area of 250,000 square mm. Materials and other characteristics of carrier 214 can be similar to carrier 204.

FIGS. 2Q, 2Q-A, and 2Q-B show signal distribution structure 101 at a later stage of manufacture. FIG. 2Q-A shows a cross-section of panel 218 taken along line A-A′ in FIG. 2Q. In the example of FIG. 2Q-A, subpanels 210 comprise individually singulated substrates 102. FIG. 2Q-B shows a cross section of panel 218 taken along line B-B′ in FIG. 2Q. In the example of FIG. 2Q-B, subpanels 210 comprise substrate blocks 202.

In the example of FIGS. 2Q, 2Q-A, and 2Q-B, insulating material 216 can be provided in channels 217 between adjacent subpanels 210 to form panel 218. Insulating material 216 can comprise an underfill, a mold material, polyimide, or other insulating materials. In some examples, insulating material 216 can comprise or be referred to as capillary underfill, non-conductive paste, spray film, spray coated dielectric, or non-conductive film. In some examples, insulating material 216 can be similar to or the same as encapsulant 208 and can be formed using transfer molding, compression molding, liquid encapsulant molding, vacuum lamination, paste printing, film assisted molding, or other suitable processes. Insulating material 216 can be coplanar with the upper side of encapsulant 208. In some examples, backgrinding or etching can be used to planarize insulating material 216. In some examples, insulating material 216 can be selected or formulated to inhibit warpage across a large panel. Panel warpage compensation channels comprising insulating material 216 can be arranged in various layouts, arrangements, or numbers. Panel warpage compensation channels can be selectively placed to increase resistance to warpage during processing.

FIGS. 2R-A and 2R-B show cross-section views of signal distribution structure 101 at a later stage of manufacture. The cross-section view of FIG. 2R-A corresponds to line A-A′ in FIG. 2Q. The cross-section view of FIG. 2R-B corresponds to line B-B′ in FIG. 2Q. In the example of FIGS. 2R-A and 2R-B, redistribution structure 106 can be provided over panel 218.

In accordance with various examples, redistribution structure 106 can be provided over subpanels 210 comprising individually singulated substrates 102 (FIG. 2R-A) or comprising substrate blocks 202 (FIG. 2R-B), and over insulating material 216 between adjacent subpanels 210. Redistribution structure 106 can include dielectric structure 126 and conductive structure 128. Conductive structure 128 can include outer terminals 128a and inner terminals 128b, which are electrically coupled to one another via various elements and/or layers (e.g., traces, vias, etc.) of conductive structure 128. Dielectric structure 126 can include one or more layers made from photo-definable organic dielectric materials such as, for example, polyimide (Pl), benzocyclobutene (BCB), or polybenzoxazole (PBO). Such dielectric materials can be spray coated or otherwise coated in liquid form, attached as a pre-formed film, or deposited in any other suitable manner for forming an electrically insulating material such as PI, BCB, PBO, or the like over panel 218. Such formation can provide dielectric structure 126 such that dielectric structure 136 is over, covers, and/or is coupled to a top side of encapsulant 208, substrates 102, and insulating material 216. In some examples, after the lowermost (or first) layer of dielectric structure 126 is provided, openings exposing an upper end of each pad 213 of can be provided. For example, after forming a mask pattern on the top side of the lowermost layer of dielectric structure 126, openings can be formed by removing exposed portions of the dielectric layer through etching. Portions of conductive structure 128 (e.g., inner terminals 128b) can then be provided in the openings, such that the portions of conductive structure 128 can couple to and/or can contact exposed upper ends of pads 213.

Formation of redistribution structure 106 can include interleaving layers of conductive structure 128 with layers of dielectric structure 126. In accordance with various examples, conductive structure 128 can be provided by electrolytic plating, electroless plating, sputtering, PVD, CVD, MOCVD, ALD, LPCVD, PECVD, or any other suitably process for deposing metals such as copper, gold, silver, aluminum, nickel, palladium, titanium, tungsten, etc. In some examples, conductive structure 128 can be provided by plating. For example, after a metal seed layer is provided to cover exposed upper ends of pads 213, and a top side of a dielectric layer of dielectric structure 126, a mask pattern can be provided to cover the top side of the metal seed layer. A conductive layer of conductive structure 128 can then be provided through plating using exposed portions of the metal seed layer as a seed. After the conductive layer is formed, the mask pattern and any portions of the seed not covered by conductive structure 128 can be removed.

Conductive structure 128 can provide electrical signal paths (e.g., vertical paths and horizontal paths) through dielectric structure 126. Conductive structure 128 can be exposed at an outer side 106a of redistribution structure 106 and can comprise outer terminals 128a along outer side 106a. In some examples, outer terminals 128a can comprise or be referred to as pads, lands, vias, or UBM. Layers and elements of conductive structure 128 can electrically couple outer terminals 128a with inner terminals 128b.

In some examples, redistribution structure 106 can be provided using a redistribution layer (RDL) build-up process and can comprise or be referred to as an RDL substrate or a build-up substrate. An RDL substrate can comprise one or more conductive redistribution layers and one or more dielectric layers and can be formed layer by layer over an electronic device (e.g., substrate 102) to which the RDL substrate is electrically coupled. RDL substrate can be manufactured layer by layer as a panel-level substrate on a rectangular or square panel carrier in a panel-level process. RDL substrates can be formed in an additive buildup process and can include one or more dielectric layers alternatingly formed with one or more conductive layers that define respective conductive redistribution pattern or traces configured to collectively (a) fan-out electrical traces outside the footprint of the electronic device, and/or (b) fan-in electrical traces within the footprint of the electronic device. The conductive pattern can be formed using a plating process such as, for example, an electroplating process or an electroless plating process. The conductive pattern can comprise an electrically conductive material such as, for example, copper or other plateable metal. The locations of the conductive pattern can be made using a photopatterning process such as, for example, a photolithography process and a photoresist material to form a photolithographic mask.

The dielectric layers of RDL substrates can be patterned with a photo-patterning process and can include a photolithographic mask through which light is exposed to photo-pattern desired features, such as vias in the dielectric layers. The dielectric layers can be made from photo-definable organic dielectric materials such as, for example, polyimide (Pl), benzocyclobutene (BCB), or polybenzoxazole (PBO). Such dielectric materials can be spray coated or otherwise coated in liquid form, attached as a pre-formed film, or deposited in any other suitable manner. To permit proper formation of photo-defined features, such photo-definable dielectric materials can omit structural reinforcers or can be filler-free, without strands, weaves, or other particles, and can interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrate can comprise one or more inorganic dielectric layers. Some examples of inorganic dielectric layers can comprise silicon nitride (Si3N4), silicon oxide (SiO2), and/or SiON. The inorganic dielectric layers can be formed by growing the inorganic dielectric layers using an oxidation or nitridization process instead of using photo-defined organic dielectric materials. Such inorganic dielectric layers can be filler-free, without strands, weaves, or other dissimilar inorganic particles. RDL substrates can omit the permanent core structure generally associated with laminate substrates (e.g., RDL substrates can be devoid of a dielectric/core material comprising bismaleimide triazine (BT) or FR4).

In accordance with various examples, redistribution structure 106 can be provided simultaneously or during the same processing steps over multiple subpanels 210 of panel 218. Redistribution structure 106 can be provided over individual substrates 102 or blocks 202. Redistribution structure 106 can substantially cover the exposed upper side of panel 218. Material of redistribution structure 106 can extend over insulating material 216 between adjacent subpanels 210.

In some examples, redistribution structure 106 can be provided over substantially coplanar surfaces of encapsulant 208 and contacts 212, as shown in the example of FIG. 2O. The coplanarity of encapsulant 208 and contacts 212 resulting from a back grinding operation can provide a substantially flat surface to build up redistribution structure 106.

FIGS. 2S-A and 2S-B show signal distribution structure 101 at a later stage of manufacture. In particular, FIGS. 2S-A and 2S-B show cross section views of panel 218 on carrier 220. The cross-section view of FIG. 2S-A corresponds to line A-A′ in FIG. 2Q. The cross-section view of FIG. 2S-B corresponds to line B-B′ in FIG. 2Q.

In the example of FIGS. 2S-A and 2S-B, panel 218 including redistribution structure 106 can be removed from carrier 214 (FIGS. 2R-A, 2R-B), and panel 218 including redistribution structure 106 can be flipped and coupled to carrier 220. Carrier 220 can be similar to or the same as carrier 214 and/or carrier 204, though carrier 220 can be larger than carrier 204. In accordance with various embodiments, a temporary bonding layer 222, similar to temporary bonding layer 206, can be disposed on the upper side of panel carrier 220, between carrier 220 and panel 218. In particular, between carrier 220 and redistribution structure 106.

In some examples, panel 218 can be placed onto carrier 220 as a single unit. In other examples, subpanels 210 can be picked and placed individually onto carrier 220. For example, panel 218 can be re-singulated through portions of redistribution structure 106 over insulating material 216 into subpanels 210 to facilitate placement of subpanels 210 onto carrier 220. Insulating material 216 can be reapplied between adjacent subpanels 210 over carrier 220, in examples where subpanels 210 are individually picked and placed.

FIGS. 2T-A and 2T-B show signal distribution structure 101 at a later stage of manufacture. In particular, FIGS. 2T-A and 2T-B show redistribution structure 104 provided over panel 218 using cross-section views. The cross-section view of FIG. 2T-A corresponds to line A-A′ in FIG. 2Q. The cross-section view of FIG. 2T-B corresponds to line B-B′ in FIG. 2Q.

In accordance with various examples, redistribution structure 104 can be provided over subpanels 210 comprising individually singulated substrates 102 (FIG. 2T-A) or substrate blocks 202 (FIG. 2T-B), and over insulating material 216 between adjacent subpanels 210. Redistribution structure 104 can include dielectric structure 136 and conductive structure 138. Conductive structure 138 can include outer terminals 138a and inner terminals 138b, which are electrically coupled to one another via various elements and/or layers (e.g., traces, vias, etc.) of conductive structure 138.

Redistribution structure 104 can be provided simultaneously or during the same processing steps over multiple subpanels 210 of panel 218. Redistribution structure 104 can substantially cover the exposed upper side of panel 218 (i.e., the side opposite carrier 220). Material of redistribution structure 104 can extend over insulating material 216 between adjacent subpanels 210. Redistribution structure 104 can be formed over the side of substrates 102 opposite redistribution structure 106. Structures and manufacturing techniques of redistribution structure 104 can be similar to or the same as those of redistribution structure 106, as previously described.

FIG. 2U shows signal distribution structure 101 at a later stage of manufacture. In the example of FIG. 2U, singulation of panel 218 can be performed. Panel 218 can be sawn or otherwise cut through saw streets S3. Singulation can separate components of panel 218 into signal distribution structures 101 having one substrate 102 per signal distribution structure 101, into strips 226 of signal distribution structures 101 having multiple individual substrates 102 (e.g., 1×n strips, 2×n strips, etc.) in each strip 226, or into strips 228 of signal distribution structures 101 having one or more substrate blocks 202 in each strip 228.

FIG. 2V shows a cross section of singulated signal distribution structures 101 taken along line V-V′ in FIG. 2U. In the example of FIG. 2V, signal distribution structure 101 includes a single substrate 102 with encapsulant 208 surrounding the substrate 102 and redistribution structures 106 and 104 formed on opposing sides of the substrate 102 and extending over the encapsulant 208. Singulation can be performed by sawing or otherwise cutting through saw streets S3 that are located between individual substrates 102. For example, sawing or cutting can be done through redistribution structure 106, encapsulant 208, and redistribution structure 106. In some examples, after singulation, the lateral sides of redistribution structure 106, encapsulant 208, and redistribution structure 106 can be coplanar. Encapsulant 208 can be located around or surround the four lateral sides of substrate 102.

FIG. 2W shows a cross-section view of singulating panel 218 into strips 226 comprising multiple substrates 102. The cross-section of FIG. 2W is taken along line W-W′ in FIG. 2U. In the example of FIG. 2W, singulation can be performed by sawing or otherwise cutting through saw streets S3 that are configured to form strips 226 that include multiple individual substrates 102. The substrates 102 in strips 226 can be coupled together with encapsulant 208. In some examples, after singulation, the lateral sides of redistribution structure 106, encapsulant 208, and redistribution structure 106 can be coplanar, and encapsulant 208 can be between adjacent substrates 102 within the strip 226. In some examples, strip 226 can also include insulating material 216. For example, a strip 226 can include substrates 102 from multiple encapsulated subpanels 210. The dimensions of strips 226 and number of substrates 102 per strip 226 can be selected based on the type of device into which the substrates 102 will ultimately be incorporated and/or on the processing capability of down the line assemblers. In this way, strips 226 can be customizable for different customers.

FIG. 2X shows a cross-section view of singulating panel 218 into strips 228 comprising blocks 202. The cross-section of FIG. 2X is taken along line X-X′ in FIG. 2U.

In the example of FIG. 2X, singulation can be performed by sawing or otherwise cutting through saw streets S3 that are configured to form strips 228 that include one or more substrate blocks 202. In this regard, at least some of the substrates 102 in strips 228 can be coupled together without any intervening encapsulant 208. In some examples, strips 228 can include substrates 102 from multiple substrate blocks 202. For example, strip 228 can include at least one portion where encapsulant 208 extends between adjacent substrates 102 (e.g., a portion from two adjacent blocks 202) and at least one portion where adjacent substrates 102 are coupled together with no intervening encapsulant 208 (e.g., a portion from within a block 202). In some examples, strips 228 can include insulating material 216. For example, strips 228 can include substrate blocks 202 from multiple subpanels 210. In some examples, after singulation, the lateral sides of redistribution structure 106, encapsulant 208, and redistribution structure 106 can be coplanar. In some examples, after singulation, the lateral sides of redistribution structure 106, insulating material 216, and redistribution structure 106 can be coplanar. The dimensions of strips 228 and number of substrate blocks 202 and substrates 102 per strip 228 can be selected based on the type of device into which the substrates 102 will ultimately be incorporated and/or on the processing capability of down the line assemblers. In this way, strips 228 can be customizable for different customers.

In some examples, signal distribution structure 101 having single substrates 102, as shown in FIG. 2X can be processed into a flip-chip ball-grid array (fcBGA) devices. In some examples, strips 226 of substrates 102 and strips 228 having substrate blocks 202 can be sent for further processing as strip-level devices such as, for example, flip-chip chip-scale packages (fcCSP). In either case, forming signal distribution structures 101 at the panel level allows for multiple substrates 102 to be processed at the same time. Larger batches enable processing of more substrates 102 per batch, which lowers costs and increases yields.

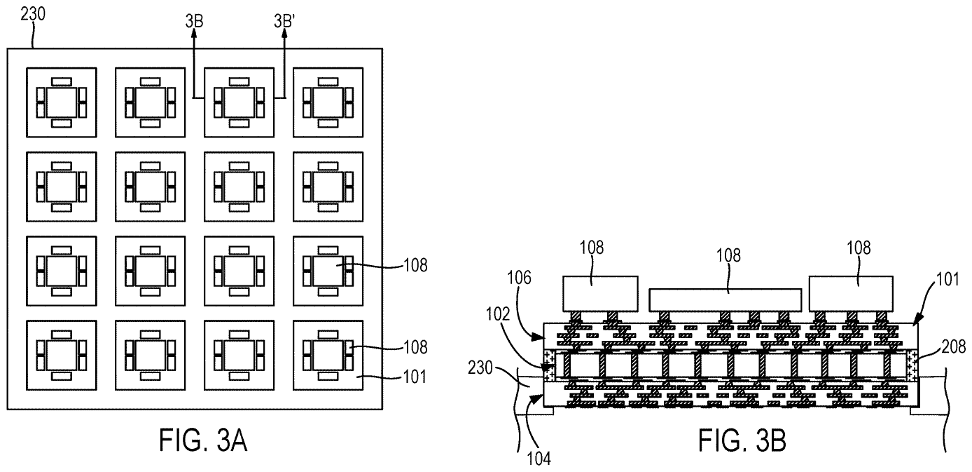

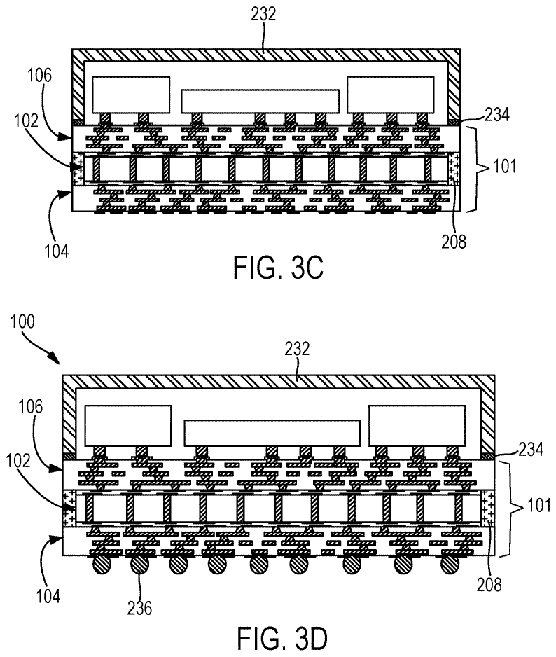

FIGS. 3A-3D show an example method of providing electronic device 100. FIG. 3A shows a plan view of electronic devices 100 at an early stage of manufacture. FIG. 3B shows a cross-section view of an electronic device 100 taken along line 3B-3B′ in FIG. 3A. In the example of FIGS. 3A and 3B, signal distribution structures 101, as formed using the method of FIGS. 2A-2V, can be placed into carrier 230 and electronic components 108 can be coupled to redistribution structure 106 of signal distribution structure 101. Carrier 230 can comprise structures and manufacturing techniques similar to or the same as those of carriers 204, 214, and 220 in some examples. In some examples, carrier 230 can comprise or be referred to as a boat, support structure, frame, plate, or other structure suitable for supporting signal distribution structure 101 during electronic component coupling.

FIG. 3C shows electronic device 100 at a later stage of manufacture. In the example of FIG. 3C, lid 232 can be provided over redistribution structure 106. Lid adhesive 234 can be coupled to redistribution structure 106 around a perimeter of electronic devices 108. Lid 232 can be coupled redistribution structure 106 via to lid adhesive 234. In the example of FIG. 3C, lid 232 extends over the tops of electronic components 108. In some examples, lid 232 can be devoid of its top plate portion, such that lid 232 forms a stiffener wall around the perimeter of electronic devices 108, but does not extend over the tops of electronic devices 108. In some examples, lid 232 can be in direct contact with electronic devices 108 and can provide heat dissipation from electronic devices 108.

FIG. 3D shows electronic device 100 at a later stage of manufacture. In the example of FIG. 3D, external interconnects 236 can be provided on bottom side of redistribution structure 104. In particular, external interconnects 236 can be provided on outer terminals 138a of conductive structure 138. In some examples, external interconnects 236 can include tin (NS), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, or Sn—Ag—Cu. For example, external interconnects 236 can be provided through a reflow process after forming a conductive material including solder on outer terminals 138a through a ball drop method. External interconnects 236 can include or be referred to as conductive balls such as solder balls, conductive pillars such as copper pillars, or conductive posts having solder caps provided on copper pillars. In some examples, external interconnects 236 can be referred to as external input/output terminals of electronic device 100.

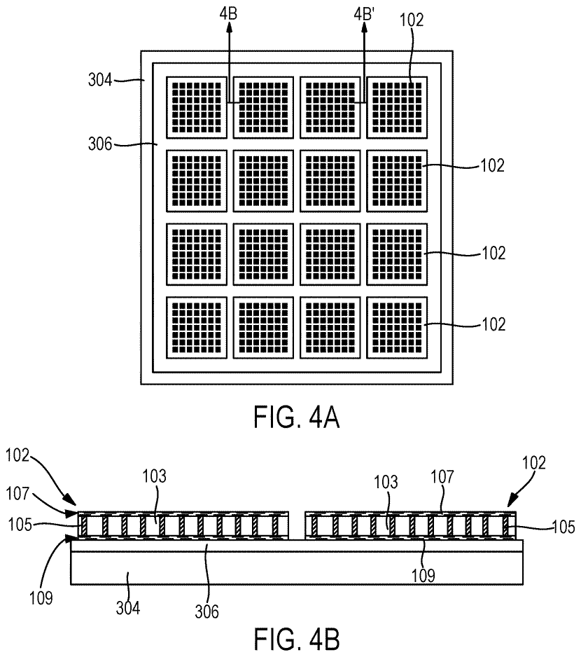

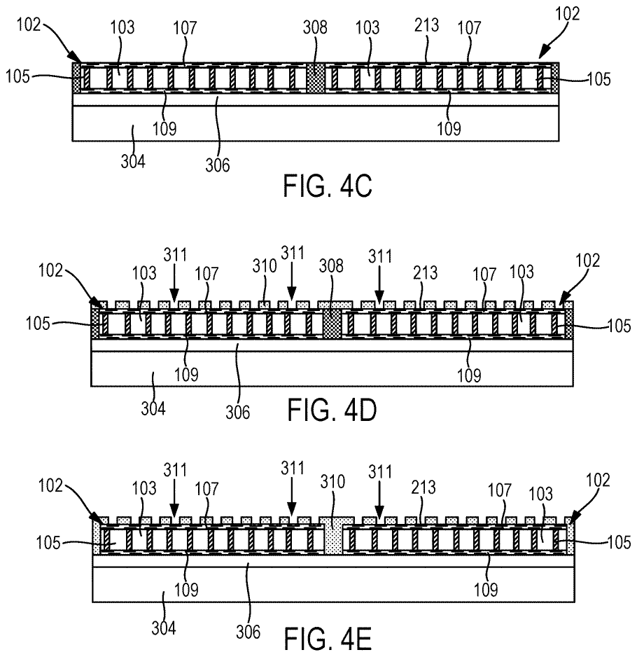

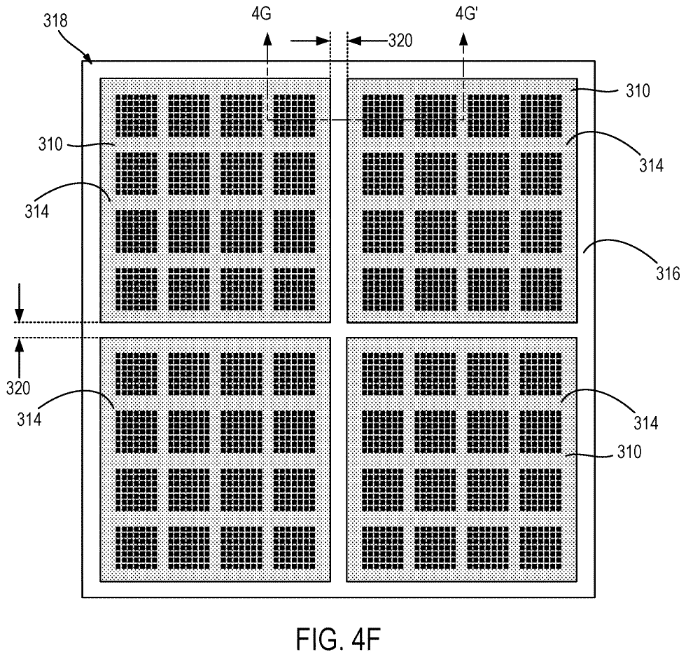

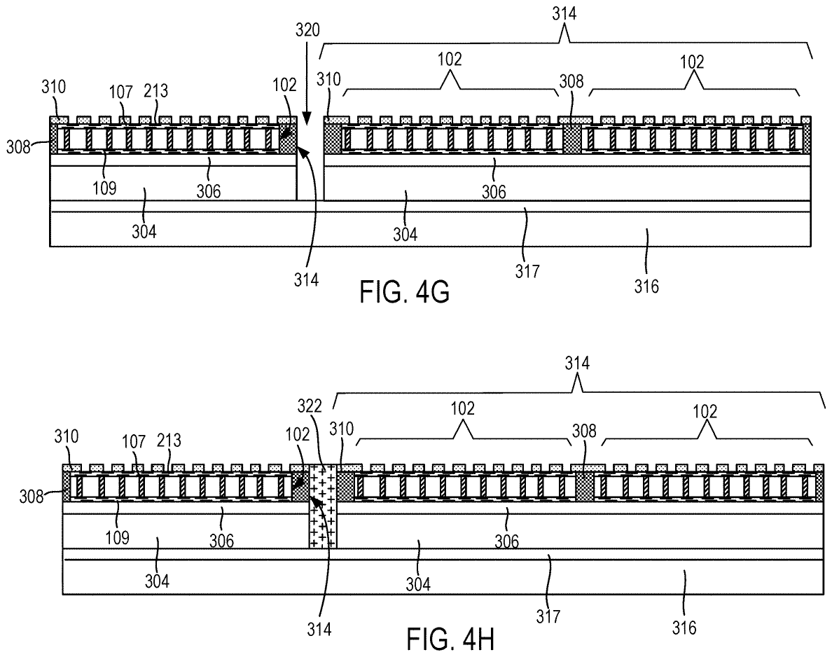

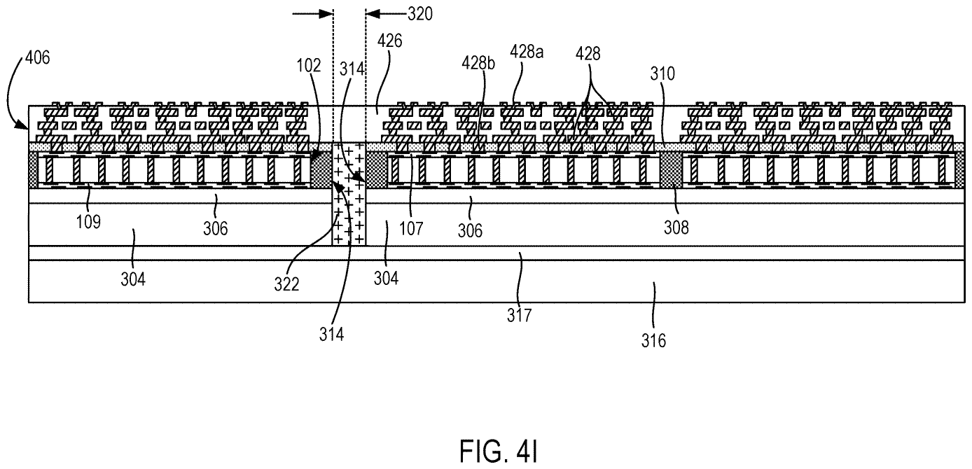

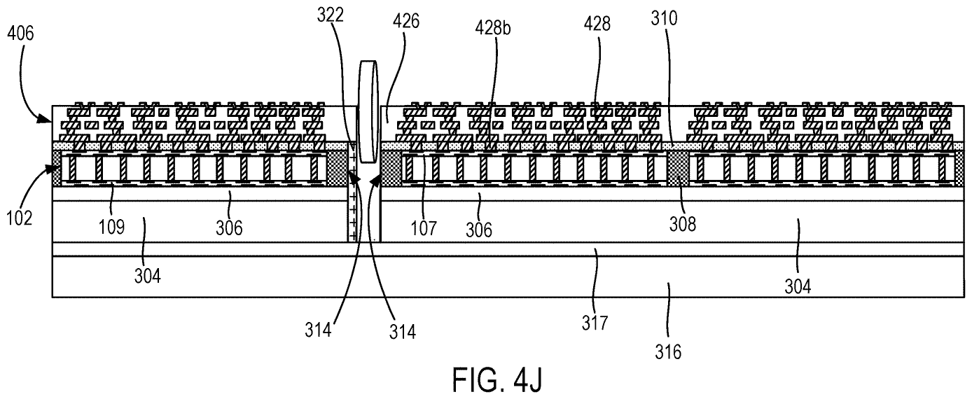

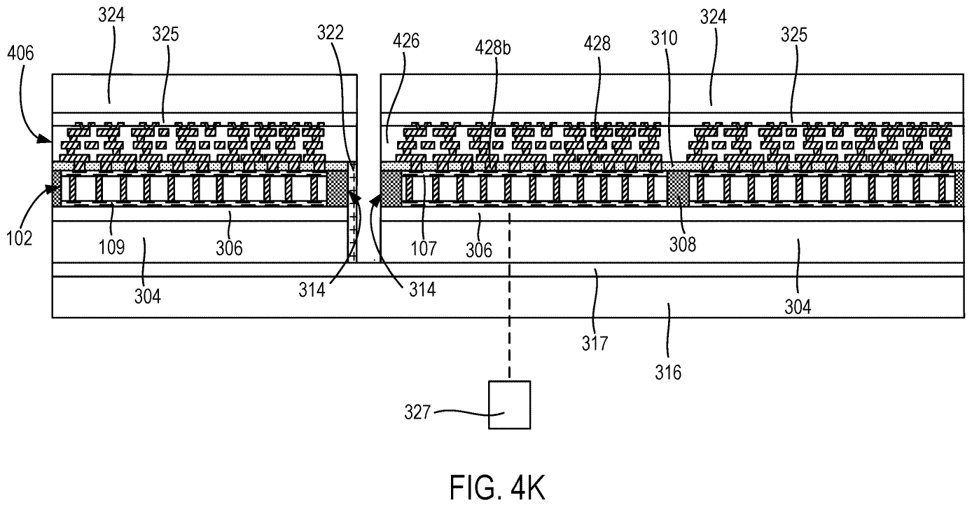

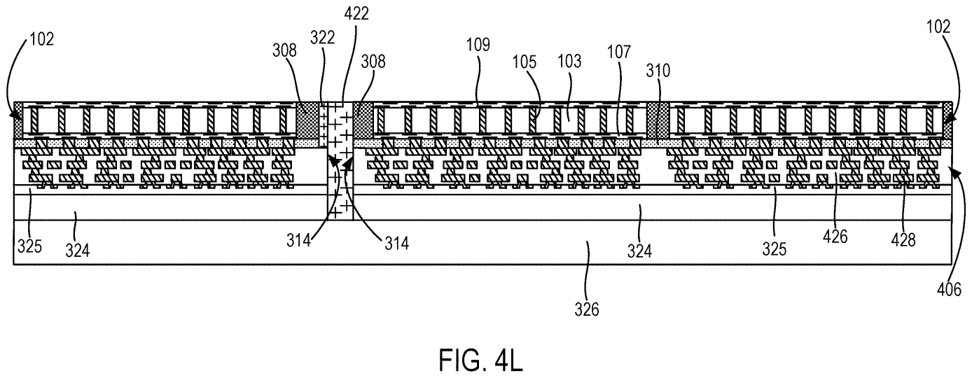

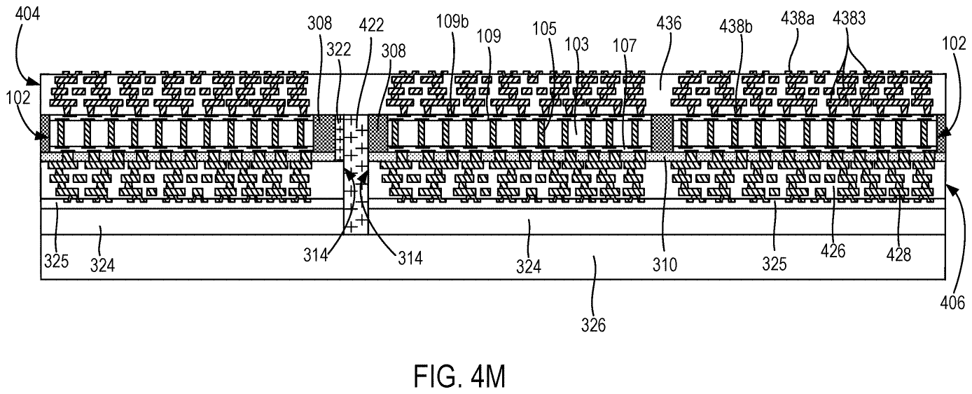

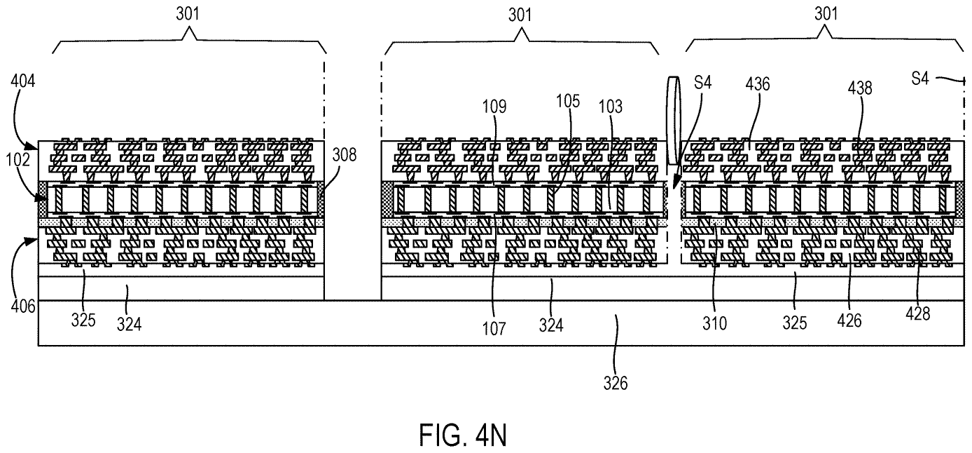

Referring now to FIGS. 4A-4N, a method of manufacturing a signal distribution structure 301 is shown, in accordance with various examples. Structures and manufacturing techniques of signal distribution structure 301 can be similar to or the same as those described herein for signal distribution structure 101 of FIGS. 1 and 2A-2X.

FIGS. 4A and 4B show a plan view and cross-section view, respectively, of signal distribution structure 301 at an early stage of manufacture. FIG. 4B is a cross section along line 4B-4B′ in FIG. 4A. In the example of FIGS. 4A and 4B, substrates 102 (or substrate blocks 202 of FIG. 2D), singulated from wafer 200, can be provided over carrier 304 to form subpanel 314. Carrier 304 can comprise structures and manufacturing techniques similar to or the same as those described herein for other carriers. In some examples, a temporary bonding layer 306 can be provided on the upper side of carrier 304 to facilitate separation of substrates 102 from carrier 304 at a later stage of manufacture. In some examples, temporary bonding layer 306 comprises a laser debondable adhesive or film configured to have its adhesive strength reduced by laser. Carrier 304 can comprise a subpanel carrier in some examples. Substrates 102 (or substrate blocks 202) can be coupled to carrier 304 by temporary bonding layer 306. Substrates 102 can be repopulated on carrier 304 in a manner similar to or the same as described above and shown in FIG. 2F.

FIG. 4C shows signal distribution structure 301 at a later stage of manufacture. In the example of FIG. 4C, a dielectric 308 can be provided between adjacent substrates 102 of subpanels 314. Dielectric 308 can be applied by spray coating, liquid injection, or other suitable deposition process. In some examples, dielectric 308 can comprise a spray coated dielectric material. The upper sides of substrates 102 and/or pads 213 of substrates 102 can remain exposed from dielectric 308. In some examples, dielectric 308 can comprise an underfill material (e.g., an epoxy-based material such as capillary underfill, non-conductive paste, etc.).

FIG. 4D shows signal distribution structure 301 at a later stage of manufacture. In the example of FIG. 4D, film 310 can be provided over substrates 102 and dielectric 308. Film 310 can comprise a dry film in some examples. Film 310 can cover the upper side of dielectric 308 in some examples. Pads 213 of substrates 102 can be exposed from film 310. For example, film 310 can have openings 311 exposing pads 213 In some examples, film 310 comprises a photo patternable material and a photopatterning process can be used to expose pads 213 from film 310.

Referring now to FIG. 4E, in some examples film 310 can be provided in the channels between adjacent substrates 102. For example, in some examples, dielectric 308 can be omitted and film 310 is applied between adjacent substrates 102 of subpanel 314. Film 310 can extend to and/or contact temporary bonding layer 306 over carrier 304. Openings 311 expose pads 213 of substrates 102.

FIGS. 4F and 4G show a plan view and a cross-section view, respectively, of signal distribution structure 301 at a later stage of manufacture. The cross-section of FIG. 4G is take along line 4G-4G′ in FIG. 4F. In the example of FIGS. 4F and 4G, subpanels 314 are placed on carrier 316 to form panel 318. Multiple subpanels 314 can be arranged on panel carrier 316 for further processing as panel 318. Gaps or channels 320 can be located between adjacent subpanels 314. Carrier 316 can comprise structures and manufacturing techniques similar to or the same as other carriers described herein, though carrier 316 can be larger than carrier 304. In some examples, a temporary bonding layer 317 can be provided on the upper side of carrier 316 to facilitate separation of subpanels 314 from carrier 316 at a later stage of manufacture. While FIG. 4G and subsequent figures show subpanels 314 having film 310 over dielectric 308, it is contemplated and understood that, in some examples, subpanels 314 with film 314 filling the gap between substrates 102 (as shown FIG. 4E) can be used to manufacture signal distribution structure 301.

In some examples, subpanels 314 can include carrier 304 when placed on carrier 316. Carriers 304 314 can support subpanels 314 during transfer to carrier 316, as dielectric 308 and/or film 310 may not provide enough rigidity to support handling of subpanels 314 without carrier 304. In some examples, the individual, singulated substrates 102 can be repopulated directly onto panel carrier 316 and dielectric 308 (e.g., spray coating) and/or film 310 (e.g., dry film application) can be provided over panel carrier 316, omitting smaller subpanel carriers 304.

FIG. 4H shows signal distribution structure 301 at a later stage of manufacture. In the example of FIG. 4H, insulating material 322 can be provided in channels 320 between adjacent subpanels 314. Insulating material 322 can comprise materials and manufacturing techniques similar to or the same as those of insulating material 216, as previously described. Insulating material 322 can be coplanar with the upper side of film 310.

FIG. 4I shows signal distribution structure 301 at a later stage of manufacture. In the example of FIG. 4I, redistribution structure 406 can be provided. Redistribution structure 406 can include dielectric structure 426 and conductive structure 428. The elements, materials, structures, and manufacturing techniques of redistribution structure 406, dielectric structure 426, and conductive structure 428, can be similar to or the same as those of redistribution structure 106, dielectric structure 126, and conductive structure 128, respectively, as previously described. Conductive structure 428 can include outer terminals 428a and inner terminals 428b, which are electrically coupled to one another via various elements and/or layers (e.g., traces, vias, etc.) of conductive structure 428. Inner terminals 428b can be coupled to and/or can contact pads 213 of substrates 102. Outer terminals 428a are exposed at the outer side of redistribution structure 406 (i.e., at the side opposite substrate 102).

Redistribution structure 406 can be provided simultaneously or during the same processing steps over multiple film subpanels 314. Redistribution structure 406 can be provided over individual substrates 102 or blocks 202. Redistribution structure 406 can substantially cover the exposed upper side of subpanels 314. Material of redistribution structure 406 can extend over dielectric 308 and/or film 310 between adjacent substrates 102 and can cover gaps 320 between adjacent subpanels 314. In some examples, insulating material 322 can provide a planar surface between adjacent subpanels 314 to facilitate formation of redistribution structure 406. In some examples, insulating material 322 can be omitted and material of dielectric structure 426 can extend into the gaps or channels 320 between adjacent subpanel 314.

FIG. 4J shows signal distribution structure 301 at a later stage of manufacture. In the example of FIG. 4J, subpanels 314 can be separated from one another. In some examples, separation of subpanels 314 can include cutting or sawing through the insulating material 322 between subpanels 314. In some examples, insulating material 322 can be completely removed from the lateral sides of subpanels 314. In some examples, a portion of insulating material 322 can remain on the lateral sides of subpanels 314.

FIG. 4K shows signal distribution structure 301 at a later stage of manufacture. In the example of FIG. 4K, carriers 324 can be provided. Carriers 324 can comprise structures and manufacturing techniques similar to or the same as other carriers described herein. Redistribution structure 406 of subpanel 314 can be coupled to carrier 324 by a temporary bonding layer 325, which can be similar or the same as other temporary bonding layers described herein.

In some examples, each subpanel 314 can be coupled to subpanel carrier(s) 324. In some examples, a laser 327 can direct and apply energy to temporary adhesive 306 to release subpanels 314 from carriers 304. The energy applied by laser 327 can reduce or remove the adhesive properties of temporary bonding layer 306, thereby allowing subpanels 314 to be separated from carrier 304. In some examples, a singulation through redistribution structure 406 and/or insulating material 322 can be performed to separate subpanels 314 from one another (as shown in FIG. 4J) and each subpanel 314 can have a dedicated subpanel carrier 324. In other examples, a single carrier 324 can be coupled to multiple subpanels 314 and the singulation step can be omitted.

FIG. 4L shows signal distribution structure 301 at a later stage of manufacture. In the example of FIG. 4L, subpanel panels 314 coupled to carrier(s) 324 can be arranged or placed on panel carrier 326. A side of substrates 102 (e.g., substrate redistribution structure 109) can be exposed and oriented away from carrier 326. Carrier(s) 324 can support subpanels 314 during transfer to carrier 326, as the materials of subpanels 314 and/or panel 318 may not have enough rigidity to support handling without carrier(s) 324. In examples comprising insulating material 322, a grinding, etching, and/or laser ablation can be performed to planarize insulating material 322 with the exposed side of substrates 102. In accordance with various examples, an insulating material 422 can be disposed between adjacent subpanels 314. Insulating material 422 can extend to carrier 326. Insulating material 422 can comprise materials and manufacturing techniques similar to or the same as those of insulating material 216, as previously described. Insulating material 422 can be coplanar with the upper sides of substrates 102 and dielectric 308.

FIG. 4M shows signal distribution structure 301 at a later stage of manufacture. In the example of FIG. 4M, redistribution structure 404 can be provided. Redistribution structure 404 can be formed over substrates 102 opposite redistribution structure 406.

Redistribution structure 404 can include dielectric structure 436 and conductive structure 438. The elements, materials, structures, and manufacturing techniques of redistribution structure 404, dielectric structure 436, and conductive structure 438, can be similar to or the same as those of redistribution structure 104, dielectric structure 136, and conductive structure 138, respectively, as previously described. Conductive structure 438 can include outer terminals 438a and inner terminals 438b, which are electrically coupled to one another via various elements and/or layers (e.g., traces, vias, etc.) of conductive structure 438. Inner terminals 438b can be coupled to conductive structure 109b of substrates 102. Outer terminals 438a are exposed at the outer side of redistribution structure 404 (i.e., at the side opposite substrate 102).

Redistribution structure 404 can be provided simultaneously or during the same processing steps over multiple subpanels 314. Redistribution structure 404 can be provided over individual substrates 102 or blocks 202. Redistribution structure 404 can substantially cover the exposed upper side of subpanels 314. Material of redistribution structure 406 can extend over dielectric 308 or film 310 between adjacent substrates 102 and can cover gaps between adjacent subpanels 314. In some examples, insulating material 422 can provide a planar surface between adjacent subpanels 314 to facilitate formation of redistribution structure 404. In some examples, insulating material 422 can be omitted and material of dielectric structure 426 can extend into the gaps or channels between adjacent subpanel 314.

FIG. 4N shows signal distribution structure 301 at a later stage of manufacture. In the example of FIG. 4N, a singulation step can be performed. Substrates 102 and subpanels 314 can be sawn through saw streets S4. Sawing can separate components of subpanels 314 into individual substrates 102, into strips including multiple substrates (e.g., similar to strips 226 in FIGS. 2U and 2W), or into strips comprising substrate blocks 202 (e.g., similar to strips 228 in FIGS. 2U and 2X). In some examples, film 310 and/or dielectric 308 can remain around the lateral sides of substrates 102 after singulation. In some examples, film 310 and/or dielectric 308 can be removed from the lateral sides of substrates 102 by singulation. In some examples, insulating material 322 or insulating material 422 (FIG. 4M) can be located at the lateral sides of signal distribution structure 301. Signal distribution structure 301 can be processed as described above and depicted in FIGS. 3A-3D, or in other manners appropriate to the unitary contents of each substrate 102 or each strip of substrates 102 or blocks 202.

Electronic devices and manufacturing techniques disclosed herein tend to improve processing times by enabling more substrates and redistribution structures to be processed at the same time. Improved processing efficiency can increase outputs and reduce costs associated with processing over a longer time and repeating processing steps.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device comprising:
a panel carrier;
a plurality of subpanels disposed over the panel carrier and defining gaps between the subpanels, the subpanels comprising substrates;
a first redistribution structure formed over a first side of the plurality of subpanels, the first redistribution structure extending across the gaps between the subpanels; and
a second redistribution structure formed over a second side of the plurality of subpanels and opposite the first side of the plurality of subpanels, the second redistribution structure extending across the gaps between the subpanels.

2. The electronic device of claim 1, further comprising an insulating material disposed in the gaps between the subpanels.

3. The electronic device of claim 2, wherein the insulating material is disposed between the first redistribution structure and the second redistribution structure.

4. The electronic device of claim 1, further comprising a film coupled to a first subpanel and extending between adjacent substrates in the first subpanel.

5. A method of manufacturing an electronic device, comprising:
singulating first substrates from a first wafer;
placing the first substrates over a first carrier;
encapsulating the first substrates to produce a first encapsulated subpanel;
singulating second substrates from a second wafer;
placing the second substrates over a second carrier;
encapsulating the second substrates to produce a second encapsulated subpanel comprising the second substrates;
placing the first encapsulated subpanel and the second encapsulated subpanel over a third carrier;
forming a first redistribution structure over a first side of the first encapsulated subpanel and the second encapsulated subpanel, the first redistribution structure extending across a gap defined between the first encapsulated subpanel and the second encapsulated subpanel; and
forming a second redistribution structure over a second side of the first encapsulated subpanel and the second encapsulated subpanel, the second redistribution structure extending across the gap defined between the first encapsulated subpanel and the second encapsulated subpanel, the second side being opposite the first side.

6. The method of claim 5, wherein encapsulating the first substrates comprises providing a mold material between the first substrates.

7. The method of claim 5, wherein encapsulating the first substrates comprises providing a dry film between the first substrates.

8. The method of claim 5, wherein encapsulating the first substrates comprises providing a spray-coated dielectric between the first substrates.

9. The method of claim 5, wherein singulating the first substrates from the first wafer includes singulating the first substrates into substrate blocks, the substrate blocks including a plurality of the first substrates coupled together.

10. The method of claim 5, further comprising:
singulating a signal distribution structure from the first encapsulated subpanel, the signal distribution structure comprising one of the first substrates coupled between a portion of the first redistribution structure and a portion of the second redistribution structure;
placing the signal distribution structure on a boat; and
coupling an electronic component to the first redistribution structure.

11. The method of claim 10, further comprising coupling a lid to the first redistribution structure around an outer perimeter of the electronic component.

12. The method of claim 5, further comprising providing component interconnects coupled to the second redistribution structure.

13. The method of claim 5, further comprising providing contacts coupled to an exposed side of the first substrates, wherein encapsulating the first substrates further comprises:
covering the first substrates and the contacts with a mold material; and
removing a portion of the mold material to expose a side of the contacts coplanar with a side of the mold material.

14. The method of claim 5, wherein the first encapsulated subpanel and the second encapsulated subpanel both comprise dimensions greater than 200 millimeters (mm) by 200 mm.

15. The method of claim 5, wherein the third carrier comprises a panel carrier having dimensions greater than 500 millimeters (mm) by 500 mm.

16. A method of making an electronic device, comprising:
providing a first subpanel on a panel carrier, the first subpanel comprising first substrates;
providing a second subpanel on the panel carrier with a gap defined between the first subpanel and the second subpanel, the second subpanel comprising second substrates;
providing a first redistribution structure over a first side of the first substrates and the second substrates, the first redistribution structure coupled to first contacts of the first substrates and second contacts of the second substrates; and
providing a second redistribution structure over a second side of the first substrates and the second substrates opposite the first side.

17. The method of claim 16, wherein the second subpanel comprises a block including at least two of the second substrates formed integrally.

18. The method of claim 16, further comprising:
providing an encapsulant around the first substrates to form the first subpanel; and
planarizing the encapsulant with contacts extending from a first side of the first substrates.

19. The method of claim 16, further comprising singulating through the first redistribution structure and the second redistribution structure to provide a strip of signal distribution structures, wherein each signal distribution structure of the strip of signal distribution structures includes a first substrate coupled between a portion of the first redistribution structure and a portion of the second redistribution structure.

20. The method of claim 16, wherein the panel carrier comprises a surface area greater than 250,000 square millimeters.
